(19) United States
(12) Patent Application Publication
(10) Pub. No.: US 2006/0267015 A1
(43) Pub. Date: Nov. 30, 2006

(54) Thin film transistor, production method thereof and liquid crystal display device

(75) Inventors: Hiroshi Omi, Fukaya-shi (JP); Mamoru Furuta, Kochi-shi (JP); Shoso Nambu, Fukaya-shi (JP); Takayoshi Dohi, Fukaya-shi (JP); Akihiro Takami, Fukaya-shi (JP); Shuji Manda, Ageo-shi (JP); Hajime Inoue, Kitaadachi-gun (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Toshiba Matsushita Display Technology Co., Ltd., Minato-ku (JP)

(21) Appl. No.: 11/411,119

(22) Filed: Apr. 26, 2006

(30) Foreign Application Priority Data
May 31, 2005 (JP) 2005-159892

(51) Int. Cl. H01L 29/04

(52) U.S. Cl. 257/59

(57) ABSTRACT

A gate electrode of a thin film transistor is composed by a three layer structure obtained by laminating a titanium nitride layer as an upper layer on an aluminum layer as a base layer and by laminating an unalloyed titanium layer as a lower layer under the base layer. An ion implantation is used as an ion doping into a source region and drain region as an active layer of the thin film transistor. The source region and the drain region are annealed at a low temperature of 350° C. to 450° C. to be activated. A chemical reaction between the base layer and the upper layer and between the base layer and the lower layer can be suppressed. The rise of the resistance value in the gate electrode can be suppressed. The resistance of the gate electrode can be reduced. The fluctuation of the threshold voltage of the thin film transistor can be suppressed.

### INCORPORATION BY REFERENCE

The present application claims priority under 35 U.S.C. §119 to Japanese Patent Application No. 2005-159892 filed on May 31, 2005. The content of the application is incorporated herein by reference in its entirety.

### FIELD OF THE INVENTION

The invention relates to a thin film transistor provided with a semiconductor layer, a method for producing the same and a liquid crystal display device.

### BACKGROUND OF THE INVENTION

Conventionally, in a thin film transistor (TFT) of a liquid crystal display device of this type, a semiconductor layer is composed by a polysilicon layer using Low-Temperature Poly-Silicon (LTPS: p-Si). The thin film transistor is annealed at 500° C. or more in order to activate impurities doped into a source region and a drain region to restore crystal defect generated by doping the impurities in the source region and drain region arranged at both sides of the semiconductor layer so as to sandwich a channel region of the semiconductor layer in the manufacture process of the liquid crystal display device. Thereby, a high melting point material such as tungsten (W), molybdenum (Mo) and molybdenum tungsten (MoW) and molybdenum tantalum (MoTa) has been used as a wiring material laminated on an active layer of the thin film transistor.

On the other hand, since the source region and drain region of the semiconductor layer do not need to be annealed at a high temperature in the production process of the liquid crystal display device composed by the thin film transistor using amorphous silicon (a-Si), a low melting point material such as aluminum (Al) and aluminum copper (AlCu) having low resistivity has been used as the wiring material.

Herein, for example, a structure described in Japanese Laid-open Patent Publication No. 2004-282066 has been known as the thin film transistor of this type. A Ti/Al alloy/Ti structure where an aluminum (Al) alloy layer is laminated on a titanium (Ti) layer and a titanium layer is laminated on this aluminum alloy layer, and a Ti/TiN/Al alloy/TiN/Ti structure where titanium nitride (TiN) layers are respectively laminated between the titanium layers and the aluminum alloy layer are described as a gate electrode of the thin film transistor using amorphous silicon (a-Si).

A structure described in, for example, Japanese Laid-open Patent Publication No. 2002-202527 has been known as the thin film transistor of this type. A Ti/Al/TiN structure where an aluminum layer is laminated on a titanium layer and a titanium nitride layer is laminated on this aluminum layer is described as the gate electrode using amorphous silicon (a-Si).

Currently, a reduction of the resistance of the wiring material used for the gate electrode of the thin film transistor has been required according to the dimension increase and high performance of the liquid crystal display device using the thin film transistor of this type. The requirement is also the same as the case that low-temperature poly-silicon is used as the semiconductor layer. Aluminum or an aluminum alloy which is a low melting point material having lower resistivity than that of the above high melting point material have already been used as the wiring material of the liquid crystal display device composed by the thin film transistor using amorphous silicon, and has been adopted as wiring in the field of the semiconductor for a long time. Thereby, since the knowledge of the aluminum and the aluminum alloy as materials is abundant, and the aluminum and the aluminum alloy are inexpensive, these are very promising as the wiring material of the gate electrode of the thin film transistor using the low-temperature poly-silicon.

However, in the production process of the thin film transistor using the low-temperature poly-silicon, the wiring material used as the gate electrode of the thin film transistor is subjected to 500° C. or more when annealing the source region and drain region of the active layer of the thin film transistor in order to activate these regions. Thereby, when the aluminum and the aluminum alloy as the low resistance materials are used as the wiring material, deformation such as the formation of hillocks as hill-like projections, voids as air gaps, constrictions and whiskers as whisker-like projections is generated on the surface of the gate electrode.

When activating the source region and drain region of the active layer of the thin film transistor, the source region and the drain region must be annealed and activated at least at 350° C. to 450° C., specifically 400° C. in order to prevent the deformation from generating on the surface of the gate electrode.

Since the gate electrode composed by the aluminum or the aluminum alloy is chemically reacted at the time of annealing and the resistance is changed when the source region and the drain region are annealed and activated at least at 350° C. to 450° C. at this time, the transistor characteristics of the thin film transistor are changed.

As the liquid crystal display device of this type, for example, the liquid crystal display device described in Japanese Laid-open Patent Publication No. 2003-8027 has been known. In the liquid crystal display device, the gate electrode of the thin film transistor is composed by laminating a titanium layer on the upper and lower sides of a base layer composed by aluminum, and thereby the above hillock is prevented.

However, even if the gate electrode of the thin film transistor is composed by laminating the titanium layer on the upper and lower sides of the base layer composed by aluminum, chemical change is generated at the boundary between the base layer of the gate electrode and the titanium layer at the time of annealing, and titaniumtrialuminide (Al₃Ti) is formed, whereby the resistance value is raised at the boundary of the base layer and the titanium layer. Thereby, since the resistance value of the gate electrode is changed, the threshold voltage (Vth) of the thin film transistor is fluctuated.

In order to solve the above problem, an object of the invention is to provide a thin film transistor capable of preventing the fluctuation of the threshold voltage, a production method thereof and a liquid crystal display device.

### SUMMARY OF THE INVENTION

The present invention provides a thin film transistor including a semiconductor layer having a channel region, and a source region and drain region provided at both sides of the channel region so as to sandwich the channel region, and composed by a polycrystal semiconductor, a gate insulating film provided on the semiconductor layer, a gate electrode provided on the gate insulating film facing the channel region, and a source electrode and drain electrode provided so as to be electrically conducted to the source region and drain region of the semiconductor layer, respectively, and the gate electrode containing: a base layer containing at least aluminum (Al), an upper layer laminated on the base layer and composed by titanium nitride (TiN), and a lower layer containing at least unalloyed titanium (Ti) laminated between the base layer and the gate insulating film.

A semiconductor layer for which a channel region and a source region and drain region are provided at both sides of the channel region so as to sandwich the channel region is composed by a polycrystal semiconductor, and a gate insulating film is provided on the semiconductor layer. Further, a gate electrode is provided on the gate insulating film facing the channel region of the semiconductor layer, a source electrode is provided so as to be electrically conducted to the source region of the semiconductor layer, and a drain electrode is provided so as to be electrically conducted to the drain region of the semiconductor layer. The gate electrode is obtained by laminating an upper layer composed by titanium nitride (TiN) on abase layer containing at least aluminum (Al) and laminating a lower layer containing at least unalloyed titanium (Ti) between this base layer and the gate insulating film. As a result, since chemical change between the base layer and upper layer of the gate electrode can be suppressed even in the semiconductor layer having the source region and drain region composed by annealing polysilicon at a comparatively low temperature, chemical change between the base layer and upper layer of the gate electrode can be suppressed, thereby the rise of the resistance value in the gate electrode can be suppressed, and thereby the fluctuation of the threshold voltage of the thin film transistor can be prevented.

### BRIEF DESCRIPTION OF THE DRAWINGS

FIG. 1 is an explanatory sectional view of a liquid crystal display device according to an embodiment of the invention;

FIG. 2 is an explanatory sectional view showing a state immediately after sputtering a gate electrode of the liquid crystal display device of the invention;

FIG. 3 is an explanatory sectional view showing a state after annealing a gate electrode of the liquid crystal display device of the invention;

FIG. 4 is an explanatory circuit block diagram showing the liquid crystal display device of the invention;

FIG. 5 is a graph showing the relationship between the annealing temperature (activation temperature) of polysilicon as a semiconductor layer of the liquid crystal display device and the sheet resistance (Rs) of the gate electrode of the invention; and

FIG. 6 is a graph showing the relationship between the annealing temperature (activation temperature) of the polysilicon and the threshold voltage (Vth) of a thin film transistor of the invention.

### DETAILED DESCRIPTION OF THE PREFERRED EMBODIMENT

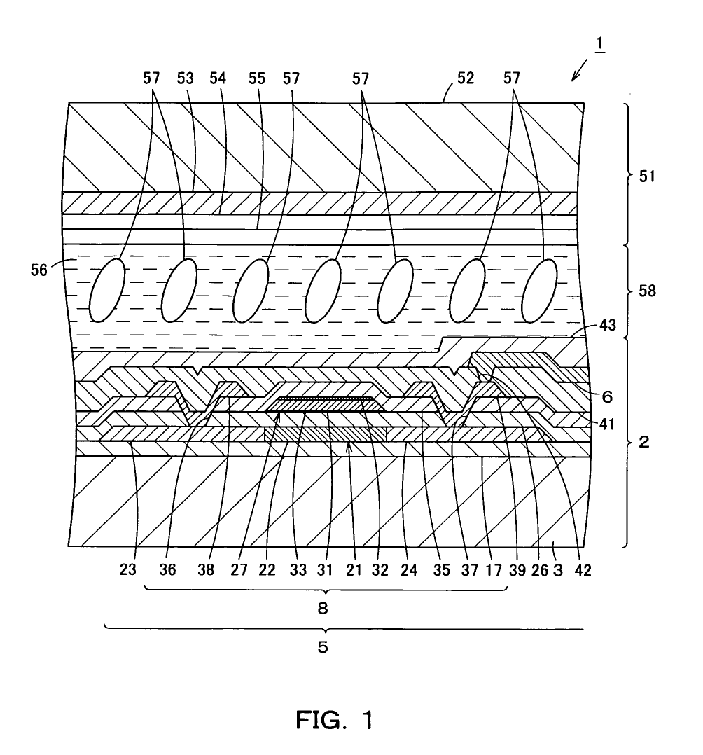

Next, the structure of a liquid crystal display device according to an embodiment of the present invention is explained in detail referring to FIG. 1 to FIG. 4.

In FIG. 1 to FIG. 4, numeral 1 denotes a liquid crystal panel as a liquid crystal display device. The liquid crystal panel 1 is an active matrix type plane display device. The liquid crystal panel 1 is provided with an array substrate 2 having a generally rectangular flat plate shape as an active matrix substrate. The array substrate 2 has a glass substrate 3 as a translucent insulating substrate being nearly transparent and having a rectangular flat plate shape.

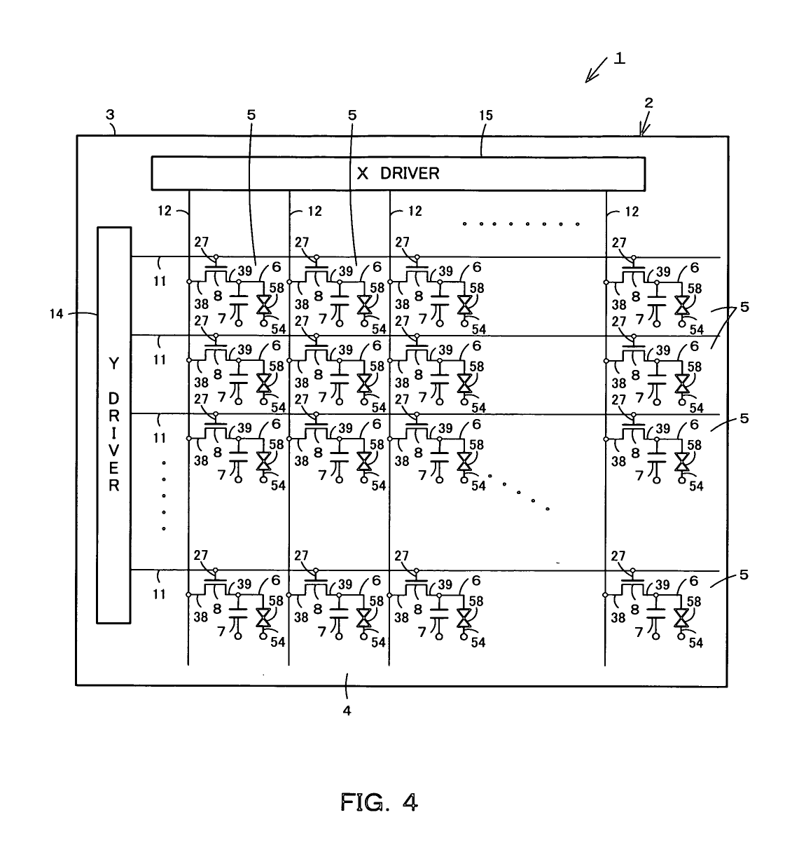

Furthermore, as shown in FIG. 4, a screen part 4 as an image display region is formed on the central part of one principal surface of the glass substrate 3. A plurality of pixels 5 are arranged in a matrix on the screen part 4 formed on the glass substrate 3. Each of the plurality of pixels 5 is provided with a pixel electrode 6, an auxiliary capacity 7 serving as a pixel auxiliary capacity as a storage capacitor, and a thin film transistor (TFT) 8.

A plurality of scanning lines 11 serving as agate electrode wiring as an electrode wiring are arranged along the width direction of the glass substrate 3 on the surface of the glass substrate 3.

These scanning lines 11 are parallely arranged at regular intervals with respect to the lateral direction of the glass substrate 3. A plurality of signal lines 12 serving as an image signal wiring as the electrode wiring are respectively arranged along the longitudinal direction of the glass substrate 3 between the scanning lines 11. The signal lines 12 are parallely arranged at regular intervals with respect to the lateral direction of the glass substrate 3. Therefore, the scanning lines 11 and the signal lines 12 are wired in a matrix as a lattice shape so that the scanning lines 11 are arranged perpendicular to the signal lines 12 on the glass substrate 3. The pixel electrode 6, the auxiliary capacity 7 and the thin film transistor 8 are provided for every pixel 5 so as to correspond to each of the intersections of the scanning lines 11 and signal lines 12.

On the other hand, a Y driver circuit 14 having an elongated rectangular flat plate shape serving as a signal line drive circuit is arranged on the periphery of the glass substrate 3. The Y driver circuit 14 is arranged along the longitudinal direction of the glass substrate 3, and is electrically connected to one end part of each of the scanning lines 11 on the glass substrate 3. An X driver circuit 15 having an elongated rectangular flat plate shape serving as a scanning line drive circuit is arranged at one end of the glass substrate 3 along the longitudinal direction. The X driver circuit 15 is electrically connected to one end part of each of the signal lines 12 on the glass substrate 3.

Next, as shown in FIG. 1, an undercoat layer 17 composed by an insulating layer is laminated and formed on the entire top surface, that is, one principal surface, of the glass substrate 3. A thin film transistor 8 of a top gate type and a coplanar type is arranged as one pixel component on the undercoat layer 17. The thin film transistor 8 is an n-type, and is a semiconductor element serving as a switching element. The thin film transistor 8 is provided with an active layer 21 serving as the semiconductor layer laminated and formed on the undercoat layer 17. The active layer 21 is a polysilicon semiconductor layer serving as a polycrystal semiconductor layer composed by Low-temperature poly-silicon (LTPS: p-Si) serving as a polycrystal semiconductor.

The active layer 21 is further provided with a channel region 22 arranged at the central part of the width direction of the active layer 21. A source region 23 and a drain region 24 are arranged so as to sandwich the channel region 22 at both side parts of the active layer 21. The source region 23 and the drain region 24 are a high concentration impurity region where impurities are doped in a high concentration, and are arranged at both side parts continued to the channel region 22. A gate insulating film 26 serving as a gate oxide film composed by silicon oxide (SiO) is laminated on the undercoat layer 17 covering the active layer 21 composed by the channel region 22, the source region 23 and the drain region 24. That is, the gate insulating film 26 is formed on the entire top surface of the undercoat layer 17 containing the active layer 21.

A gate electrode 27 serving as a gate wiring composed by a wiring material having conductivity is laminated at a position facing the channel region 22 of the active layer 21 on the gate insulating film 26. As shown in FIG. 4, the gate electrode 27 is integrally connected to one side edge of the scanning line 11, and constitutes a part of the scanning line 11. That is, the gate electrode 27 is electrically connected to the scanning line 11. The gate electrode 27 has a width dimension approximately equal to that of the channel region 22 of the active layer 21, and is formed on the channel region 22 via the gate insulating film 26. Therefore, the gate electrode 27 is provided facing an interval on the channel region 22 of the active layer 21.

Herein, the gate electrode 27 is provided with a layer containing at least aluminum (Al), for example, a base layer 31 composed by an aluminum layer. The base layer 31 is composed by an aluminum film serving as a base material having a film thickness of 150 nm or more, for example, 300 nm. An upper layer 32 serving as a barrier metal layer composed by titanium nitride (TiN) is laminated on the base layer 31. The upper layer 32 contains titanium nitride film obtained by nitriding titanium, and for example, the upper layer 32 having a film thickness of 20 nm is formed.

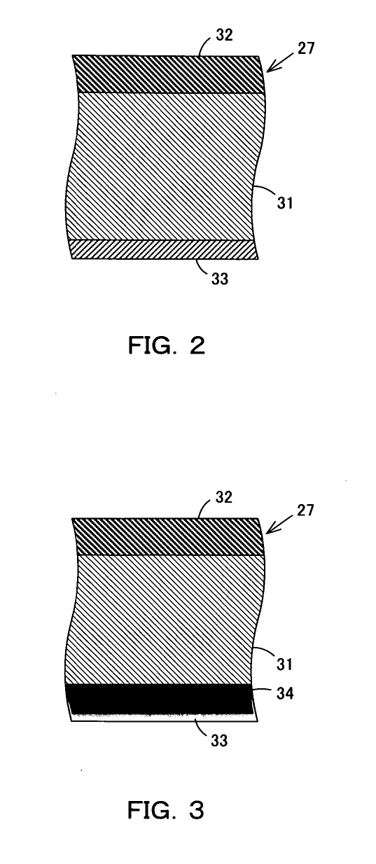

A layer containing at least titanium (Ti) as a main component, for example, a lower layer 33 serving as a metal layer composed by a titanium layer, is laminated under the base layer 31. The lower layer 33 is unalloyed without melting and mixing metal elements and non-metal elements or the like other than titanium, and is a pure titanium layer mostly composed by only titanium. That is, the lower layer 33 is not a eutectic body containing the metal elements and the non-metal elements or the like other than the titanium, and is composed by mutually metal-bonding titanium atoms. Furthermore, the lower layer 33 is interposed and laminated between the base layer 31 and the gate insulating film 26. The lower layer 33 having a film thickness of 10 nm or more, for example, 40 nm is formed. Furthermore, as shown in FIG. 2, the lower layer 33 having a smaller film thickness dimension than that of the upper layer 32 in a state immediately after sputtering, for example, a film thickness dimension approximately half of that of the upper layer 32 is formed. Each of the base layer 31, upper layer 32 and lower layer 33 having an equal width dimension is formed, and is laminated upward in the order of the lower layer 33, base layer 31 and upper layer 32.

Furthermore, as shown in FIG. 2, the lower layer 33 of the gate electrode 27 is laminated as the titanium layer under the base layer 31 in a so-called as-sputter state immediately after sputtering the gate electrode 27. As shown in FIG. 3, referring to the lower layer 33, titanium and aluminum are mutually diffused at a boundary part between the lower layer 33 and the base layer 31 in a state after annealing impurities doped into the source region 23 and drain region 24 of the active layer 21 at 350° C. to 450° C., for example, 400° C. to activate the impurities, and a titanium-aluminum mutual diffusion layer 34 is formed. Therefore, the base layer 31 having a film thickness in which the resistance value of the gate electrode 27 is not fluctuated by the mutual diffusion between the base layer 31 and the lower layers 34 due to annealing is formed.

An interlayer insulating film 35 serving as a silicon oxide film having insulation is laminated on the gate insulating film 26 covering the gate electrode 27 composed by a structure of laminating the base layer 31, upper layer 32 and lower layer 33. Contact holes 36 and 37 penetrating each of the interlayer insulating films 35 and the gate insulating film 26 and serving as a conducting part electrically conducting and the source region 23 and drain region 24 of the active layer 21 are opened in the interlayer insulating film 35 and the gate insulating film 26. Herein, the contact hole 36 is communicated with the source region 23 of the active layer 21, and the contact hole 37 is communicated with the drain region 24 of the active layer 21.

A source electrode 38 serving as metal signal wiring having conductivity is laminated on the interlayer insulating film 35 containing the contact hole 36. The source electrode 38 is electrically connected to the source region 23 of the active layer 21 via the contact hole 36. Furthermore, a drain electrode 39 serving as a metal signal wiring having conductivity is laminated on the interlayer insulating film 35 containing the contact hole 37. The drain electrode 39 is electrically connected to the drain region 24 of the active layer 21 via the contact hole 37. Furthermore, the source electrode 38 and the drain electrode 39 are provided in a state of being electrically insulated via a predetermined gap. That is, the source electrode 38 and the drain electrode 39 are formed at both sides of the gate electrode 27 via the gate electrode 27. Furthermore, the source electrode 38 is electrically connected to the signal line 12.

An insulating passivation film 41 serving as a protective film is laminated on the entire top surface of the interlayer insulating film 35 covering the source electrode 38 and the drain electrode 39. A contact hole 42 penetrating the passivation film 41 and serving as a through hole as a conducting part electrically conducting the drain electrode 39 is opened in the passivation film 41. The contact hole 42 is communicated with the drain electrode 39. The pixel electrode 6 composed by an ITO film serving as a transparent conductive film is laminated on the passivation film 41 containing the contact hole 42. The pixel electrode 6 is electrically connected to the drain electrode 39 via the contact hole 42. An alignment film 43 composed by polyimide (PI) subjected to a rubbing process is laminated on the entire top surface of the passivation film 41 containing the pixel electrode 6.

On the other hand, a counter substrate 51 having a rectangular flat plate shape is arranged facing the array substrate 2. The counter substrate 51 is provided with a glass substrate 52 serving as a translucent insulating substrate being nearly transparent and having a rectangular flat plate shape. A color filter layer 53 is laminated on one principal surface of the side of the glass substrate 52 facing the array substrate 2. Furthermore, a counter electrode 54 composed by an ITO (Indium Tin Oxide) film serving as a transparent conductive film is laminated on the glass substrate 52 containing the color filter layer 53. An alignment film 55 composed by polyimide subjected to a rubbing process is laminated on the counter electrode 54. A liquid crystal composition 57 is injected into a liquid crystal sealing region 56 serving as a gap between the alignment film 55 and the alignment film 43 of the array substrate 2, and a liquid crystal layer 58 serving as an optical modulation layer is interposed in the liquid crystal sealing region 56.

Next, a method for producing the liquid crystal display device of the above embodiment will be explained.

First, the undercoat layer 17 is laminated and deposited on the glass substrate 3.

Then, an amorphous silicon film (not shown) serving as an amorphous semiconductor is laminated and deposited on the undercoat layer 17.

Next, the amorphous silicon film is irradiated with an energy beam such as an excimer laser beam to anneal the amorphous silicon film. The amorphous silicon film is fused, crystallized, and polycrystallized, and a polysilicon film is formed. The polysilicon film is then patterned and is arranged like an island.

Next, the gate insulating film 26 is laminated and deposited in TEOS (Tetraethoxysilane: Si (OC₂H₅)₄) using a plasma CVD (Chemical Vapor Deposition) method on the entire top surface of the undercoat layer 17 containing the patterned polysilicon film like an island.

Then, the titanium layer, the aluminum layer and the titanium nitride layer are sequentially laminated on the entire top surface of the gate insulating film 26 in the order of the titanium layer, aluminum layer and titanium nitride layer (not shown) by the sputtering method.

At this time, the titanium nitride layer is formed by a reactive sputtering using a target and nitrogen (N₂) gas composed by titanium.

The gate electrode 27 having a laminating structure where the base layer 31 is laminated on the lower layer 33 and the upper layer 32 is laminated on the base layer 31 is then formed on the central part of the width direction of the polysilicon film by patterning the titanium layer, the aluminum layer and the titanium nitride layer like an island.

In this state, the source region 23 and the drain region 24 are formed by injecting n-type impurities, for example, boron (B) into both sides of the polysilicon film like an island in a high concentration by ion doping (I/D) due to ion implantation (I/I) mainly doping desired ions and having high performance using the gate electrode 27 as a mask.

At this time, the region between the source region 23 and drain region 24 of the polysilicon film like an island is the channel region 22, and the polysilicon film like an island is the active layer 21.

Next, the impurities injected into the source region 23 and the drain region 24 of this active layer 21 are annealed and activated at 350° C. to 450° C. or less as a comparatively low temperature, for example, 400° C., and the crystal defect generated by doping the impurities to the source region 23 and the drain region 24 is restored.

The interlayer insulating film 35 is laminated and deposited on the gate insulating film 26 containing the gate electrode 27.

Then, after forming a resist (not shown) on the entire top surface except for a portion where the contact holes 36 and 37 of the interlayer insulating film 35 are provided, the contact holes 36 and 37 communicated with the source region 23 and drain region 24 of the active layer 21 are respectively opened by patterning the interlayer insulating film 35 and the gate insulating film 26.

Next, a metal film is formed on the interlayer insulating film 35 containing the contact holes 36 and 37 after exfoliating the resist on the interlayer insulating film 35, and the metal film is then patterned. The source electrode 38 and the drain electrode 39 are respectively formed to obtain the thin film transistor 8.

Then, the passivation film 41 is laminated and deposited on the interlayer insulating film 35 containing the source electrode 38 and the drain electrode 39. The passivation film 41 is then patterned, and the contact hole 42 communicated with the drain electrode 39 is opened.

The pixel electrode 6 is then laminated and deposited on the passivation film 41 containing the contact hole 42, and the alignment film 43 is then laminated and deposited on the passivation film 41 containing the pixel electrode 6.

Furthermore, the alignment film 55 of the counter substrate 51 faces the alignment film 43, and the counter substrate 51 and the array substrate 2 are bonded. The liquid crystal composition 57 is injected into the liquid crystal sealing region 56 between the alignment film 43 of the array substrate 2 and the alignment film 55 of the counter substrate 51, and the liquid crystal layer 58 is interposed to obtain the liquid crystal panel 1.

Herein, in order to restore the crystal defect generated by doping the impurities into the source region 23 and drain region 24 of the active layer 21 of the thin film transistor 8 in the thin film transistor 8 having the active layer 21 composed by the low-temperature poly-silicon, when the source region 23 and drain region 24 of the active layer 21 are respectively activated by high temperature annealing, the base layer 31 composed by the aluminum of the gate electrode 27 is chemically reacted with the lower layer 33 composed by the titanium under the base layer 31. As shown in FIG. 3, since the titanium-aluminum mutual diffusion layer 34 is formed between the base layer 31 and the lower layer 33, the resistance of the gate electrode 27 is raised.

Similarly, even when the metal layer which is composed by the titanium or the like and is not shown is inserted between the base layer 31 of the gate electrode 27 and the upper layer 32 laminated on the base layer 31 and composed by the titanium nitride, since the aluminum of the base layer 31 is chemically reacted with the titanium of the titanium layer, and the titanium-aluminum mutual diffusion layer 34 is formed, the threshold voltage (Vth) of the thin film transistor 8 is fluctuated.

Then, as shown in the above embodiment, the gate electrode 27 of the thin film transistor 8 having the active layer 21 composed by the low-temperature poly-silicon has a three layer structure where the upper layer 32 composed by the titanium nitride is laminated on the base layer 31 composed by the aluminum, and the lower layer 33 composed by the titanium is laminated under the base layer 31. Furthermore, the ion implantation is used as ion doping into the source region 23 and drain region 24 of the active layer 21 of the thin film transistor 8.

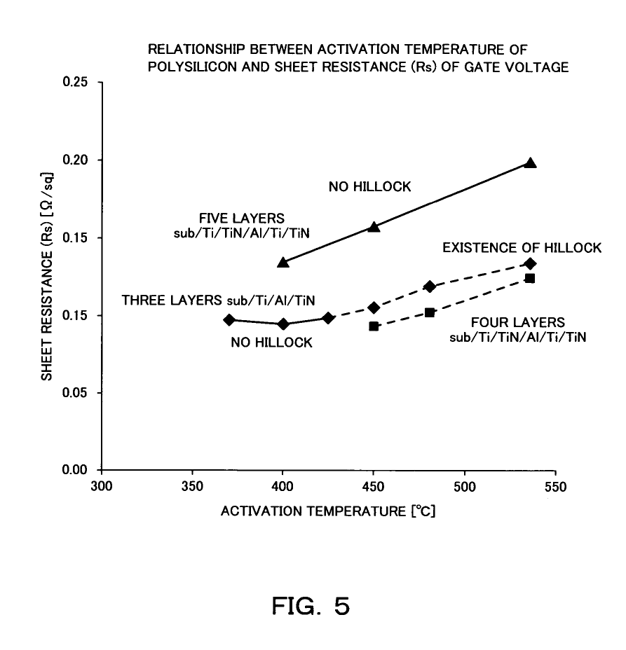

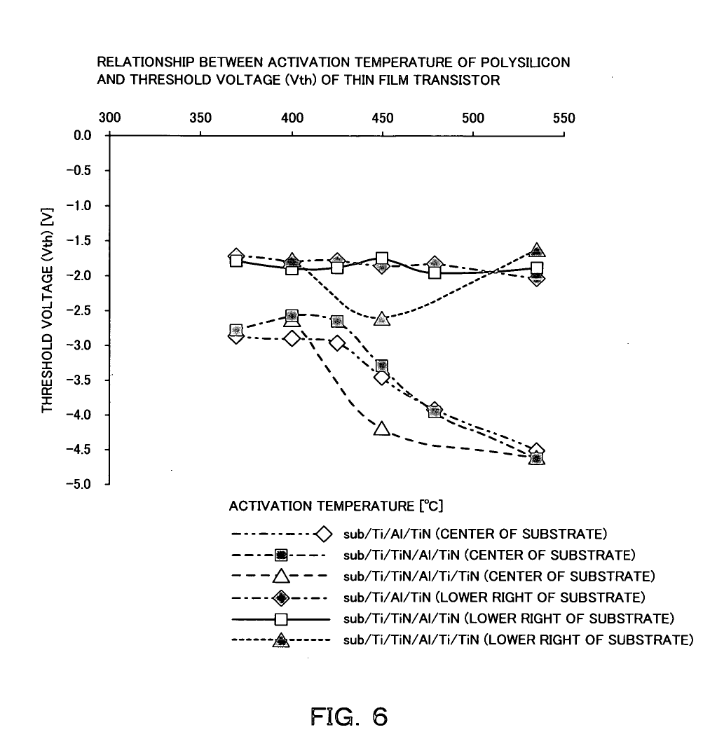

As a result, even when the source region 23 and drain region 24 of the active layer 21 of the thin film transistor 8 are respectively annealed and activated at a low temperature of 350° C. to 450° C. as a comparatively low temperature, the chemical reaction between the base layer 31 and the upper layer 32, and between the base layer 31 and the lower layer 33 can be suppressed. Therefore, as shown in FIG. 5, even when the three layer structure of Ti/Al/TiN is annealed at 350° C. to 450° C., the rise of the sheet resistance (Rs) value of the gate electrode 27 can be suppressed without the appearance of the hillock, and the resistance of the gate electrode 27 can be reduced. Thereby, the fluctuation of the threshold voltage of the thin film transistor 8 can be suppressed. As shown in FIG. 6, the fluctuation of the threshold voltage of the thin film transistor 8 can be suppressed within the range of the temperature change of the central part of the glass substrate 3 on the central part of the glass substrate 3 where the threshold voltage of the thin film transistor 8 is easily fluctuated. Therefore, the thin film transistor 8 having good transistor characteristics can be obtained.

That is, the fluctuation of the threshold voltage in the base layer 31 of the thin film transistor 8 can be prevented by removing and omitting the titanium layer (not shown) for preventing the hillock between the base layer 31 and upper layer 32 of the gate electrode 27. Furthermore, the upper layer 32 of the gate electrode 27 of the thin film transistor 8 is composed by the titanium nitride, and thereby the upper layer 32 located on the surface of the gate electrode 27 is hardly etched when electrically conducting to the contact hole (not shown) by wet-etching the interlayer insulating film 35 or the like on the gate electrode 27. Therefore, since the rise of the resistance value due to the etching of the gate electrode 27 can be prevented, the reduction of the reliability of the wiring of the gate electrode 27 can be prevented, and the fluctuation of the threshold voltage of the thin film transistor 8 can be prevented.

When the film thickness of the lower layer 33 of the gate electrode 27 of the thin film transistor 8, the film thickness of the base layer 31, and the film thickness of the upper layer 32 are respectively set to 20 nm, 300 nm and 40 nm, the experiment result shows that the threshold voltage of the thin film transistor 8 can be improved by about 1V as compared with the thin film transistor having a five layer structure (Specifically, the titanium nitride layer having a film thickness of 40 nm is laminated on the lower layer 33 having a film thickness 20 nm. The base layer 31 having a film thickness of 300 nm is laminated on the titanium nitride layer, and the titanium layer having a film thickness of 10 nm is laminated on the base layer 31. The upper layer 32 having a film thickness 40 nm is laminated on the titanium layer).

The temperature at the time of annealing the source region 23 and drain region 24 of the active layer 21 of the thin film transistor 8 is set to 350° C. to 450° C., more optimally 360° C. to 420° C., specifically about 400° C., and thereby it is found that the threshold voltage of the thin film transistor 8 can be improved by about 1V as compared with the thin film transistor having the above five layer structure. It is found that the chemical reaction between the titanium and the aluminum can be suppressed between the lower layer 33 and the base layer 31 by lowering the temperature at the time of the anneal to 400° C., and the resistance rise of the gate electrode 27 can be suppressed.

When the film thickness of the base layer 31 of the gate electrode 27 is set to less than 150 nm, the thickness of the base layer 31 is reduced by the formation of the titanium-aluminum mutual diffusion layer 34 due to the chemical reaction between the base layer 31 and the lower layer 33 generated by annealing the source region 23 and drain region 24 of the active layer 21 of the thin film transistor 8, and the thickness is substantially eliminated. Thereby, the resistance value of the gate electrode 27 may be raised. Therefore, it is necessary to set the film thickness of the base layer 31 of the gate electrode 27 to 150 nm or more.

When the film thickness of the lower layer 33 of the gate electrode 27 is reduced to less than 10 nm, the entirety of the lower layer 33 is composed by the titanium-aluminum mutual diffusion layer 34 by the chemical reaction between the base layer 31 and the lower layer 33 due to the annealing of the source region 23 and drain region 24 of the active layer 21 of the thin film transistor 8. Thereby, the threshold voltage of the thin film transistor 8 is fluctuated, and it is necessary to set the film thickness of the lower layer 33 of the gate electrode 27 to 10 nm or more.

Although the liquid crystal panel 1 in which the liquid crystal layer 58 as the optical modulation layer is inserted between the array substrate 2 and the counter substrate 51 is explained in the above embodiment, for example, the present invention can also be applied to a plane display device such as an organic self-emission-type display device in which an Electro Luminescence (EL) material as an organic luminescent material is used as the optical modulation layer in place of the liquid crystal material, that is, an electroluminescence display device.

Although the n-type thin film transistor 8 in which n-type impurities are doped into each of the source region 23 and drain region 24 is composed, the present invention can also be applied to the p-type thin film transistor 8 in which p-type impurities, for example, phosphorous (P) are doped into each of the source region 23 and drain region 24, and an LDD (Lightly Doped Drain) region (not shown) referred to as a low concentration impurity region is interposed between the source region 23 and the channel region 22, and the drain region 24 and the channel region 22.

What is claimed is:

1. A thin film transistor comprising:
a semiconductor layer having a channel region, and a source region and drain region provided at both sides of the channel region so as to sandwich the channel region, and composed by a polycrystal semiconductor;
a gate insulating film provided on the semiconductor layer;
a gate electrode provided on the gate insulating film facing the channel region; and
a source electrode and drain electrode provided so as to be electrically conducted to the source region and drain region of the semiconductor layer, respectively, and the gate electrode containing:
a base layer containing at least aluminum (Al);
an upper layer laminated on the base layer and composed by titanium nitride (TiN); and
a lower layer containing at least unalloyed titanium (Ti) laminated between the base layer and the gate insulating film.

2. The thin film transistor according to claim 1, wherein the base layer of the gate electrode having a film thickness of 150 nm or more is formed.

3. The thin film transistor according to claim 1, wherein the lower layer of the gate electrode having a film thickness 10 nm or more is formed.

4. The thin film transistor according to claim 1, wherein the lower layer of the gate electrode contains at least titanium (Ti) as a main component.

5. The thin film transistor according to claim 1, wherein the lower layer of the gate electrode is a titanium layer.

6. A liquid crystal display device comprising:
an array substrate having the thin film transistor according to claim 1;
a counter substrate arranged facing the array substrate; and
a liquid crystal layer interposed between the array substrate and the counter substrate.

7. A method for producing a thin film transistor comprising the steps of:
laminating a polycrystal semiconductor on an insulating substrate to form a semiconductor layer;
laminating a gate insulating film on the insulating substrate so as to cover the semiconductor layer;
forming a gate electrode at a position facing the central part of the semiconductor layer on the gate insulating film, the gate electrode containing a base layer containing at least aluminum (Al), an upper layer laminated on the base layer and composed by titanium nitride (TiN), and a lower layer laminated between the base layer and the gate insulating film and containing at least unalloyed titanium (Ti);
doping both side parts of the semiconductor layer using the gate electrode as a mask to form a source region and a drain region and to set the semiconductor layer between the source region and the drain region to a channel region; and
annealing the source region and drain region of the semiconductor layer at 350° C. to 450° C. to activate the source region and the drain region.

8. The method for producing the thin film transistor according to claim 7, wherein the lower layer of the gate electrode contains at least titanium (Ti) as a main component.

9. The method for producing the thin film transistor according to claim 7, wherein the lower layer of the gate electrode is a titanium layer.
